(19) United States
(12) Patent Application Publication
(10) Pub. No.: US 2011/0095335 A1
(43) Pub. Date: Apr. 28, 2011

(54) NITRIDE SEMICONDUCTOR DEVICE

(75) Inventors: Hidetoshi Ishida, Osaka (JP); Yasuhiro Uemoto, Shiga (JP); Masahiro Hikita, Hyogo (JP)

(73) Assignee: PANASONIC CORPORATION, Osaka (JP)

(21) Appl. No.: 13/001,825

(22) PCT Filed: Jul. 2, 2009
(86) PCT No.: PCT/JP2009/003063

§ 371 Date: Dec. 29, 2010

(30) Foreign Application Priority Data
Jul. 3, 2008 (JP) 2008-175066

(51) Int. Cl. H01L 29/06

(52) U.S. Cl. 257/190; 257/E29.024

(57) ABSTRACT

A high breakdown voltage GaN-based transistor is provided on a silicon substrate. A nitride semiconductor device including: a silicon substrate, a SiO₂ layer stacked on the silicon substrate and having a film thickness 100 nm or more; a silicon layer stacked on the SiO₂ layer; a buffer layer stacked on the silicon layer; a GaN layer stacked on the buffer layer; an AlGaN layer stacked on the GaN layer; and a source electrode, a drain electrode, and a gate electrode that are formed on the AlGaN layer, and edge sidewalls of the silicon layer, the buffer layer, the GaN layer, and the AlGaN layer contact an increased-resistivity region.

### TECHNICAL FIELD

The present invention relates to a nitride semiconductor device, and relates particularly to improving voltage withstand characteristics of a power device using a nitride semiconductor such as GaN.

### BACKGROUND ART

Recent years have seen a power device market steadily growing, and the market size thereof had expanded to reach nearly 2 trillion yen in 2006. The insulated gate bipolar transistor (IGBT) and metal oxide semiconductor field effect transistor (MOSFET) are major devices on this market. Performances of such devices are improved each day, and have already achieved a level of extracting a material limit of silicon. Thus, what is expected to emerge next is a device using a new power semiconductor material which has properties exceeding a property limit of silicon. In this context, due to its extremely high potentiality as a power device material, GaN has rapidly been developed as a power device material for the next generation. Besides having a feature of high breakdown field as compared to silicon, a GaN-based material can induce, when forming a heterojunction with an AlGaN layer and a GaN layer, two-dimensional electron gas of high sheet carrier concentration of 10¹³ (cm⁻²) order to an interface between these materials. For this reason, the GaN-based material is an extremely promising material for realizing a field-effect transistor (FET) used for a power device.

Conventionally, the GaN-based material has been heteroepitaxially grown on a sapphire substrate or a SiC substrate, whereas a technique of growing a GaN-based material on a silicon substrate has recently been developed. As a result, active research and development has been promoted in a GaN-based transistor on the silicon substrate.

The following will describe, with reference to FIG. 12, a conventional FET using a nitride semiconductor material on a silicon substrate as disclosed in Patent Literature 1. FIG. 12 is a cross-sectional view of a conventional GaN-based transistor formed on the silicon substrate. A GaN-based transistor 500 in the figure includes: a silicon substrate 501, a transition layer 502, a GaN-based material layer 503, a source electrode 504, a gate electrode 505, a drain electrode 506, and a passivation film 507. The transition layer 502 has a function to reduce cracking or warpage caused by a difference between thermal expansion coefficients of the silicon substrate 501 and the GaN-based material layer 503. The GaN-based transistor 500 can function as a field-effect transistor by forming the GaN-based material layer 503 into a heterojunction AlGaN/GaN.

In addition, Patent Literature 1 discloses that it is possible to use, as the silicon substrate 501, silicon on insulator (SOI), silicon on sapphire (SOS), separation by implanted oxygen (SIMOX), or the like.

### CITATION LIST

### Patent Literature

[PTL 1] U.S. Pat. No. 7,071,498, Description

### SUMMARY OF INVENTION

### Technical Problem

However, the conventional GaN-based transistor on the silicon substrate described above has a problem of having a low breakdown voltage of the device.

In the conventional GaN-based transistor, when the gate voltage to turn off the transistor is set to, for example, −5V with reference to the source electrode, and then the drain voltage is gradually applied, device breakdown occurs before the drain voltage grows sufficiently high. In practice, such a state and causes thereof have not been sufficiently considered so far.

Thus, we have repeated studies with commitment so as to clarify the cause of such a low breakdown voltage of the conventional GaN-based transistor on the silicon substrate. FIG. 13A is a circuit diagram of the GaN-based transistor on the silicon substrate. Specifically, a current flowing into each of the drain, gate, source, and substrate is measured using a circuit shown in FIG. 13A, to observe a behavior of the current at each terminal until device breakdown occurs. FIG. 13B is a graph showing a measurement result of each current with respect to the drain voltage. The figure shows that most of a drain current flows into the silicon substrate as a substrate current. Our experiments have clarified that this inflowing substrate current causes breakdown.

In addition, we formed a GaN-based transistor with the same configuration on a sapphire substrate, and focused on a result that such a GaN-based transistor formed on the sapphire substrate indicates an extremely high breakdown voltage of the device as compared to that on the silicon substrate. The fact has led us to realize a problem of the low breakdown voltage of the GaN-based device on the silicon substrate.

Thus, application of a substrate including a SOI structure or a p-n junction to the silicon substrate has been considered. However, our experiment has verified that it is difficult to increase breakdown voltage by simply applying the SOI structure. To realize a higher-withstand device, it is necessary to further increase the device structure in addition to the application of the SOI structure.

The present invention is conceived in view of the above problem, and it is an object of the present invention to provide a high breakdown voltage nitride semiconductor device on the silicon substrate.

### Solution to Problem

To solve the above problems, a nitride semiconductor device according to an aspect of the present invention includes: a silicon substrate; a current suppression layer which is stacked on the silicon substrate and suppresses current flowing into the silicon substrate; a buffer layer stacked on the current suppression layer; a first nitride semiconductor layer stacked on the buffer layer; a second nitride semiconductor layer stacked on the first nitride semiconductor layer and having a bandgap greater than a bandgap of the first nitride semiconductor layer; and an electrode formed on the second nitride semiconductor layer, and an edge sidewall of each of the buffer layer, and the first and second nitride semiconductor layers contacts an increased-resistivity region.

According to the aspect of the present invention, the current suppression layer, which is formed between the electrode and the silicon substrate, allows suppressing the substrate current flowing from the electrode to the substrate even when the potential of the electrode is increased, thus increasing breakdown voltage. As a result, it is possible to prevent device breakdown. Furthermore, since at least sidewalls of the buffer layer and the first and second nitride semiconductor devices contact the region having increased resistivity, it is possible to effectively suppress the leakage current flowing from the electrode into the silicon substrate via the sidewalls.

In addition, the increased-resistivity region may be a region formed by implanting ions into part of a perimeter of the buffer layer and the first and second nitride semiconductor layers.

In forming the buffer layer and the first and second nitride semiconductor layers, implanting ions in at least part of a perimeter of the buffer layer and the first and second nitride semiconductor devices results in a configuration in which at least the sidewalls of the buffer layer and the first and second nitride semiconductor devices contact the increased-resistivity region. According to the present aspect, it is possible to realize a configuration which increases resistivity of a region that easily passes the leakage current.

In addition, the increased-resistivity region may be a region formed by removing, by etching, part of a perimeter of the buffer layer and the first and second nitride semiconductor layers.

When formation of the buffer layer and the first and second nitride semiconductor layers is completed, removing at least part of a perimeter of the buffer layer and the first and second nitride semiconductor devices by etching results in a configuration in which at least the sidewalls of the buffer layer and the first and second nitride semiconductor devices contact the increased-resistivity region. In the present aspect, it is also possible to realize a configuration which increases resistivity of the region that easily passes the leakage current, thus allowing reliably suppressing the substrate current.

In addition, the nitride semiconductor device may further include a silicon layer formed between the current suppression layer and the buffer layer, and having an edge sidewall in contact with the increased-resistivity region, and the current suppression layer may be a SiO₂ layer having a film thickness of 100 nm or more.

According to the present aspect, SiO₂ having a very high breakdown electric field can effectively suppress the substrate current flowing from the electrode to the silicon substrate.

In addition, it is preferable that the film thickness of the SiO₂ layer be 3 μm or less.

According to the present aspect, it is possible to increase breakdown voltage without increasing thermal resistance of the device.

In addition, it is preferable that the resistivity of the silicon layer be 1 k Ωcm or more.

According to the present aspect, since the silicon layer on SiO₂ functions as an insulator, a longitudinal voltage of the device is divided among all the layers including the SiO₂ layer in addition to the first nitride semiconductor layer and the buffer layer, thus allowing further increasing breakdown voltage.

In addition, it is preferable that a surface orientation of the silicon layer be tilted at 5 degrees or less with respect to a (111) surface.

According to the present aspect, crystallinity of the buffer layer and the first and second nitride semiconductor layers grown on the silicon layer is extremely satisfactory. As a result, it is possible to reduce crystal fault that causes leakage of current flowing from the electrode into the silicon substrate, thus effectively increasing breakdown voltage of the device.

In addition, it is preferable that the film thickness of the silicon layer be 5 μm or less.

According to the present aspect, the silicon layer becomes completely depleted and can control a phenomenon in which a transient current passes through the silicon layer that contacts the insulating layer when the transistor function is turned on and off. Thus, it is possible to suppress heat generation caused by turning on and off of the transistor.

In addition, it is preferable that the buffer layer include a polycrystalline AlN layer, and a single-crystal AlN layer formed on the polycrystalline AlN layer.

According to the present aspect, the presence of the single-crystal AlN layer can remove an electron-accumulating layer derived from the polarization charge formed at the interface of the single-crystal AlN layer 113 and the silicon layer 103, thus further increasing breakdown voltage.

In addition, the nitride semiconductor device according to the present aspect may further include a high-resistivity layer formed between the current suppression layer and the buffer layer, and the high-resistivity layer may be a sapphire layer having a film thickness of 100 nm or more.

According to the present aspect, since the sapphire layer on the silicon substrate is an insulator having an extremely high resistivity, a longitudinal voltage of the device is divided among all the layers including the sapphire layer in addition to the first nitride semiconductor layer and the buffer layer, thus allowing increasing breakdown voltage.

In addition, the nitride semiconductor device according to the present aspect may further include a high-resistivity layer formed between the current suppression layer and the buffer layer, and the high-resistivity layer may be a SiC layer having a film thickness of 100 nm or more.

According to the present aspect, the first and second nitride semiconductor layers have higher crystallinity because the SiC layer on the silicon layer has high resistivity, and because the SiC layer, as compared to sapphire, has a lattice constant close to that of the first nitride semiconductor layer, thus allowing increasing breakdown voltage.

In addition, the current suppression layer may be an n-type silicon layer having an edge sidewall in contact with the increased-resistivity region, and the silicon substrate may be a p-type silicon substrate.

According to the present aspect, when the electrode is positively biased with respect to the silicon substrate, a depletion layer is formed as a result of reverse biasing of the p-n junction, thus allowing realizing higher breakdown voltage.

In addition, it is preferable that the film thickness of the n-type silicon layer may be 5 μm or more.

With this, it is possible to realize a sufficient reverse breakdown voltage of the p-n junction.

In addition, it is preferable that the n-type silicon layer have a carrier concentration of 5×10¹⁵ cm⁻³ or less.

With this, it is possible to realize a sufficient reverse breakdown voltage of the p-n junction.

In addition, it is preferable that the buffer layer include a periodic structure in which a heterostructure including an Al_{X}Ga_{1-X}N layer (0≦X<1) and an Al_{Y}Ga_{1-Y}N layer (0<Y≦1) is repeated.

With this, since multiple heterobarriers are formed between the electrode and the silicon substrate, it is possible to realize a high breakdown voltage.

### ADVANTAGEOUS EFFECTS OF INVENTION

According to a semiconductor device in an implementation of the present invention, it is possible to increase breakdown voltage and also suppress leakage current between an electrode and a silicon substrate. As a result, occurrence of breakdown between the electrode and the substrate is suppressed, thus allowing realizing a high breakdown voltage transistor.

### BRIEF DESCRIPTION OF DRAWINGS

FIG. 1 is a cross-sectional view of a configuration of a nitride semiconductor device according to a first embodiment of the present invention.

FIG. 2 is a cross-sectional view of a configuration of a nitride semiconductor device according to a first variation of the first embodiment of the present invention.

FIG. 3A is a graph showing a relationship between leakage current and applied voltage in the case of an unprocessed device edge, based on a film thickness of a SiO₂ layer as a parameter.

FIG. 3B is a graph showing a relationship between leakage current and applied voltage in the case of a device edge having increased resistivity, based on a film thickness of a SiO₂ layer as a parameter.

FIG. 4 is a graph showing dependence of breakdown voltage and thermal resistance on a film thickness of a SiO₂ layer in the nitride semiconductor device according to the first embodiment of the present invention.

FIG. 5 is a graph showing a relationship between an orientation of a silicon layer and crystallinity of a GaN layer in the nitride semiconductor device according to the first embodiment of the present invention.

FIG. 6A is a top view and a cross-sectional view of a configuration of a nitride semiconductor device according to a second variation of the first embodiment of the present invention.

FIG. 6B is a perspective view of the nitride semiconductor device according to the second variation of the first embodiment of the present invention.

FIG. 7 is a cross-sectional view of a configuration of a nitride semiconductor device according to a third variation of the first embodiment of the present invention.

FIG. 8 is a cross-sectional view of a configuration of a nitride semiconductor device according to a fourth variation of the first embodiment of the present invention.

FIG. 9 is a cross-sectional view of a configuration of a nitride semiconductor device according to a second embodiment of the present invention.

FIG. 10 is a graph showing dependence of breakdown voltage on a film thickness of an n-type silicon-layer in the nitride semiconductor device according to the second embodiment of the present invention.

FIG. 11 is a graph showing a relationship between a carrier concentration and breakdown voltage of the n-type silicon layer included in the nitride semiconductor device according to the second embodiment of the present invention.

FIG. 12 is a cross-sectional view of a conventional GaN-based transistor formed on the silicon substrate.

FIG. 13A is a circuit diagram of the GaN-based transistor on the silicon substrate.

FIG. 13B is a graph showing a measurement result of each current with respect to drain voltage, in the GaN-based transistor on the silicon substrate.

### DESCRIPTION OF EMBODIMENTS

### Embodiment 1

A nitride semiconductor device according to the present embodiment includes a silicon substrate on which: an insulating film, a silicon layer, a buffer layer, a first nitride semiconductor layer, a second nitride semiconductor layer having a greater bandgap than the first nitride semiconductor layer, and an electrode are stacked in this order. Furthermore, edge sidewalls of the silicon layer, the buffer layer, and the first and the second nitride semiconductor layers contact a region having increased resistivity. With this, a portion between the electrodes and the silicon substrate is insulated by an insulating film, and leakage current due to crystal fault, and furthermore leakage current via a device edge is suppressed, so that it is possible to suppress substrate current flowing from the electrodes into the substrate even when the potential of the electrodes increases, thus allowing preventing breakdown of the nitride semiconductor device.

The following will describe the first embodiment of the present invention with reference to the drawings.

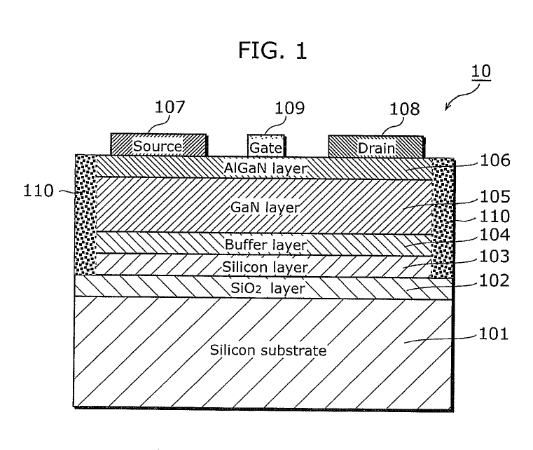

FIG. 1 is a cross-sectional view of a configuration of a nitride semiconductor device according to the first embodiment of the present invention. A nitride semiconductor device 10 in the figure includes: a silicon substrate 101, a SiO₂ layer 102, a silicon layer 103, a buffer layer 104, a GaN layer 105, an AlGaN layer 106, a source electrode 107, a drain electrode 108, a gate electrode 109, and an increased-resistivity region 110.

The SiO₂ layer 102 is a current suppression layer which suppresses current flowing from the electrodes in an upper potion to the silicon substrate, and is stacked on the silicon substrate 101 and has a film thickness of 100 nm or more. The SiO₂ layer 102 has a function to secure breakdown voltage as a transistor for the nitride semiconductor device 10.

Note that in order to secure the above breakdown voltage, the breakdown voltage between the silicon substrate 101 and the drain electrode 108 should preferably be 100 V or higher.

The silicon layer 103 includes Si and is stacked on the SiO₂ layer 102, with specific resistance 100 Ωcm and plane orientation (111). The orientivity of the silicon layer 103 influences crystallinity of the buffer layer 104, the GaN layer 105, and the AlGaN layer 106 that are stacked thereon. Accordingly, the plane orientation of the silicon layer 103 should preferably be tilted at 5° or less with respect to (111).

The buffer layer 104 is a first buffer layer stacked on the silicon layer 103, and has a function to reduce a difference between thermal expansion coefficients of the silicon layer 103 that is a lower layer and the GaN layer 105 and the AlGaN layer 106 that are upper nitride semiconductor layers. For material, for example, a film stack which is AlN or a combination of AlN, AlGaN, and GaN is applicable.

The GaN layer 105 is a first nitride semiconductor layer stacked on the buffer layer 104, and includes GaN that is a semiconductor having a large bandgap.

The AlGaN layer 106 is a second nitride semiconductor layer stacked on the GaN layer 105, and includes AlGaN that is a semiconductor having a greater bandgap than the GaN layer 105 that is the lower layer. In addition, the AlGaN layer 106 has a stoichiometric composition ratio of, for example, Al_{0.2}Ga_{0.8}N.

The GaN layer 106 functions as a channel layer, inducing two-dimensional electron gas of a high sheet carrier concentration of 10¹³ (cm⁻²) order to an interface with the AlGaN layer 106. In addition, the AlGaN layer 106 has a function as an electron-supplying layer which supplies electrons to the interface described above.

The source electrode 107, the drain electrode 108, and the gate electrode 109 are formed on the AlGaN layer 106, and function as electrodes. The source electrode 107 and the drain electrode 108 include a Ti/Al-based material, and the gate electrode 109 includes Ni/Au or Pd/Pt/Au.

Furthermore, the device edge includes the increased-resistivity region 110, which is formed by ion implantation using boron or the like and suppresses leakage current at the device edge.

The increased-resistivity region 110 contacts the edge sidewalls of the silicon layer 103, the buffer layer 104, the GaN layer 105, and the AlGaN layer 106. This configuration of the increased-resistivity region 110 allows suppressing, between the silicon substrate 101 and each of the source electrode 107, the drain electrode 108, and the gate electrode 109, the leakage current passing via the edge sidewalls of the silicon layer 103, the buffer layer 104, the GaN layer 105, and the AlGaN layer 106. Thus, it is possible to realize a configuration which increases resistivity of a region that easily passes the leakage current, and thereby to suppress the substrate current flowing from the electrodes into the substrate even when the potential of the electrodes is increased, thus allowing preventing breakdown of the nitride semiconductor device.

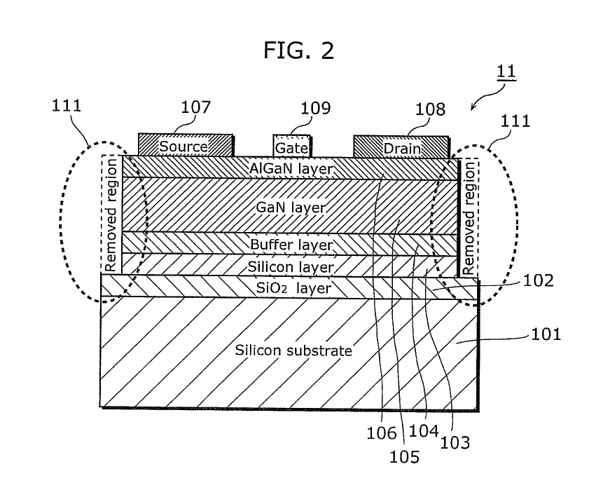

In addition, the increased-resistivity region 110 can be formed by etching the material as shown in a cross-sectional view of the configuration shown in FIG. 2.

FIG. 2 is a cross-sectional view of the configuration of a nitride semiconductor device according to a first variation of the first embodiment of the present invention. A nitride semiconductor device 11 in the figure includes: the silicon substrate 101, the SiO₂ layer 102, the silicon layer 103, the buffer layer 104, the GaN layer 105, the AlGaN layer 106, the source electrode 107, the drain electrode 108, and the gate electrode 109. The nitride semiconductor device 11 shown in FIG. 2 is different from the nitride semiconductor device 10 shown in FIG. 1 in that the increased-resistivity region 110 is replaced with a removed region 111. The following will omit the description of the same points as those described in the nitride semiconductor device 10 in FIG. 1, and will only describe the difference.

The removed region 111 is a region formed by: forming, on the silicon substrate 101, the SiO₂ layer 102, the silicon layer 103, the buffer layer 104, the GaN layer 105, and the AlGaN layer 106 in this order, and then removing, by etching, part of a perimeter of the silicon layer 103, the buffer layer 104, the GaN layer 105, and the AlGaN layer 106. Here, the SiO₂ layer 102 may function as an etching stop layer.

The removed region 111 contacts the edge sidewalls of the silicon layer 103, the buffer layer 104, the GaN layer 105, and the AlGaN layer 106. This configuration of the removed region 111 allows suppressing, between the silicon substrate 101 and each of the source electrode 107, the drain electrode 108, and the gate electrode 109, the leakage current passing via the edge sidewalls of the silicon layer 103, the buffer layer 104, the GaN layer 105, and the AlGaN layer 106. Thus, it is possible to realize the configuration which increased resistivity of the region that easily passes the leakage current, and thereby to suppress the substrate current flowing from the electrodes into the substrate even when the potential between the electrodes is increased, thus preventing breakdown of the nitride semiconductor device.

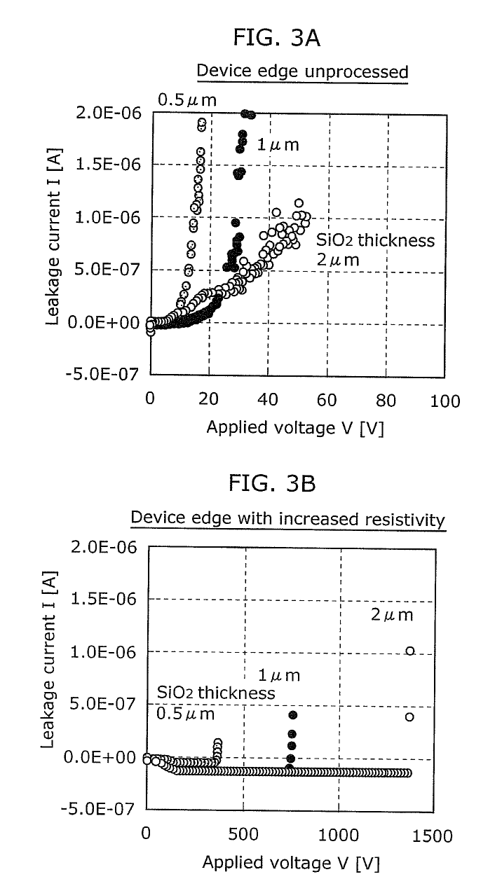

FIGS. 3A and 3B show, by comparison, effects produced by edge leakage control formed as shown in FIG. 2.

FIG. 3A is a graph showing a relationship between leakage current and applied voltage in the case of an unprocessed device edge, based on a film thickness of the SiO₂ layer as a parameter. FIG. 3B is a graph showing a relationship between leakage current and applied voltage, based on the film thickness of the SiO₂ layer as a parameter, in the case of a device edge having increased resistivity. As indicated by a graph in FIG. 3A, in the case of the device edge without increased resistivity, a large volume of leakage current flows despite the thickness of the SiO₂ layer, thus not allowing achieving high breakdown voltage characteristics. On the other hand, as indicated by a graph in FIG. 3B, it is clear that an increase in film thickness of the SiO₂ layer 102 increases breakdown voltage in the configuration including the processed device edge having increased resistivity. Thus, the processing for increasing resistivity of the device edge surface is extremely important.

With the configuration described above, each of the nitride semiconductor devices 10 and 11 according to the embodiment of the present invention functions as a high-power field-effect transistor. For example, increasing, in a positive direction, a threshold or higher voltage that is to be applied to the gate 109 increases the drain current passing through the GaN layer 105 that is a channel layer.

The following will describe an operation of the above-described nitride semiconductor devices 10 and 11 as a field-effect transistor when the transistor is in an off-state. In this off-state, by setting the voltage between the gate electrode 109 and the source electrode 107 to a threshold voltage of the transistor or lower to −5V, for example, a positive voltage of 200 V, for example, is applied to the drain electrode 108. In this state, nearly 200 V is applied between the drain electrode 108 and the source electrode 107; however, by providing a large distance of, for example, approximately 5 μm between the drain electrode 108 and the gate electrode 109, a sufficient breakdown voltage can be secured between the gate and drain electrodes, thus causing no breakdown.

Here, breakdown voltage is a maximum voltage that an element can withstand when turning off, through gate voltage control, the nitride semiconductor device that is a transistor; that is, a limit voltage at which device breakdown occurs.

On the other hand, this results in applying a large electric field between the drain electrode 108 and the silicon substrate 101. The inventors of the present invention have found out that device breakdown occurs between the drain electrode and the silicon substrate in the conventional transistor. In contrast, in the nitride semiconductor device 10 according to an implementation of the present invention, the electric field is applied to the SiO₂ layer 102, so that no device breakdown occurs between the drain electrode 108 and the silicon substrate 101, thus realizing, as a result, a high breakdown voltage transistor.

Note that any plane orientation of the silicon substrate 101 may be adopted, such as (100) and (111).

In addition, when the SiO₂ layer 102 is too thick, the heat generated in the transistor cannot effectively be released into the silicon substrate 101, thus degrading performance of the transistor.

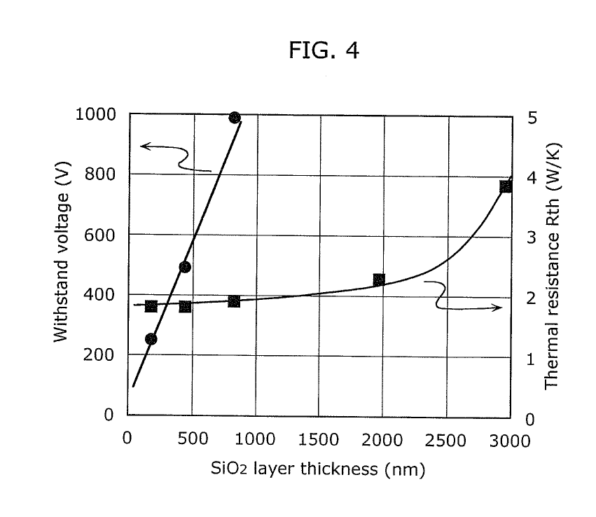

FIG. 4 is a graph showing dependence of breakdown voltage and thermal resistance on the film thickness of the SiO₂ layer in the nitride semiconductor device according to the first embodiment of the present invention. A graph in the figure indicates that a greater film thickness of the SiO₂ layer 102 further increases the withstand characteristics of the nitride semiconductor devices 10 and 11. On the other hand, the graph indicates that the greater the film thickness of the SiO₂ layer 102 is, the higher the thermal resistance, particularly indicating that the thermal resistance significantly increases when the film thickness of the SiO₂ layer 102 is in a range of 3 μm or more. Thus, the thickness of SiO₂ layer 102 should be 3 μm or less depending on the intended use of the nitride semiconductor device 10.

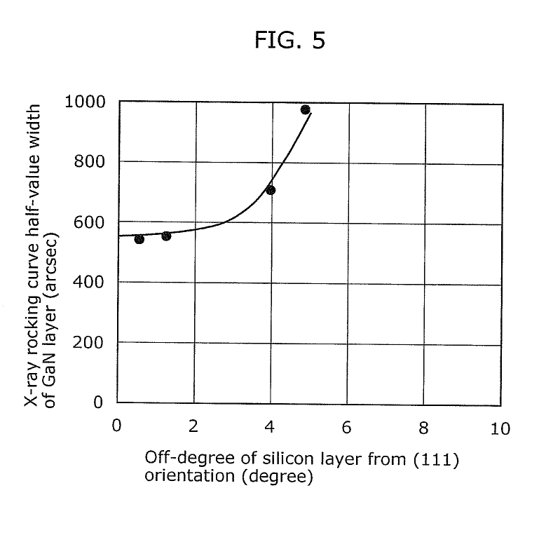

FIG. 5 is a graph indicating a relationship between an orientation of the silicon layer and crystallinity of the GaN layer in the nitride semiconductor device according to the first embodiment of the present invention. In the graph shown in the figure, a horizontal axis indicates a tilt of plane orientation of the silicon layer 103 with respect to the (111) plane, and a vertical axis indicates a full width at half maximum of an X-ray diffracted waveform of the GaN layer 105. The graph shown in the figure implies that the crystallinity of the GaN layer 105 significantly deteriorates due to a tilt of plane orientation larger than 5°.

In addition, the film thickness of the silicon layer 103 should preferably be 5 μm or less. When the film thickness is greater than 5 μm, the silicon layer 103 does not become depleted, so that transient current passes through the silicon layer 103 when the transistor function is turned on and off, thus resulting in a problem of heat generation within the device.

In addition, for example, it is preferable that the buffer layer 104 have a periodic structure in which a heterostructure including an Al_{X}Ga_{1-X}N layer (0≦X<1) and an Al_{Y}Ga_{1-Y}N layer (0<Y≦1) is repeated, and particularly have a structure in which a heterostructure of AlN and GaN is periodically stacked into multiple layers. Since this configuration includes multiple heterobarriers against electrons, carrier conduction between the drain electrode and the silicon substrate is suppressed, thus allowing further increasing breakdown voltage between the drain electrode and the silicon substrate.

Note that the nitride semiconductor devices 10 and 11 described in FIGS. 1 and 2 illustrate only a semiconductor chip which includes a unit made up of the gate electrode 109, the source electrode 107, and the drain electrode 108; however, even in the case of including, as a constituent element, a semiconductor chip in which a plurality of such units are arranged, the same advantageous effect can be produced as with the nitride semiconductor devices 10 and 11 described in FIGS. 1 and 2.

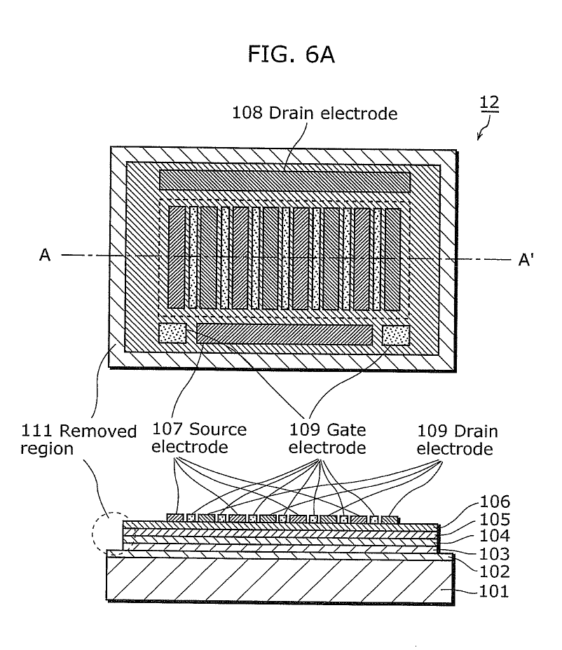

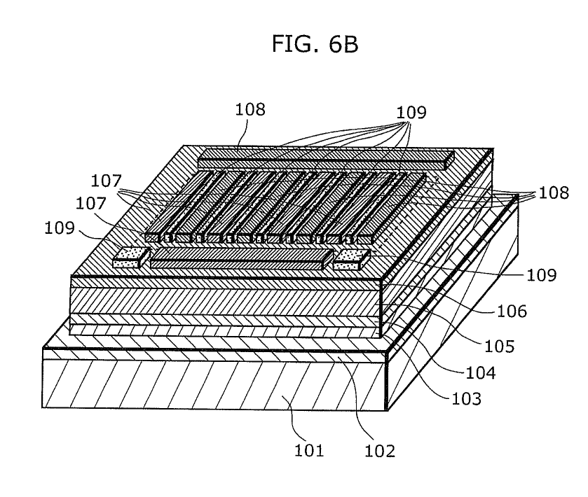

FIG. 6A is a top view and a cross-sectional view of the configuration of a nitride semiconductor device according to a second variation of the first embodiment of the present invention. In addition, FIG. 6B is a perspective view of the nitride semiconductor device according to the second variation of the first embodiment of the present invention. A nitride semiconductor device 12 shown in FIGS. 6A and 6B is included in a multiple-finger transistor chip. The nitride semiconductor device 12 is included in a semiconductor chip in which: units each including the gate electrode 109, the source electrode 107, and the drain electrode 108 are arranged in parallel, and electrode pads connected to each of the electrodes are provided on both sides of the units. Note that as shown in the cross-sectional view of the configuration shown in FIG. 6A, a layered structure including the silicon substrate 101 to AlGaN layer 106 has the same structure as the nitride semiconductor devices 10 and 11 described in FIGS. 1 and 2.

In the nitride semiconductor device 12 having the above structure, the removed region 111 is disposed at part of a perimeter of the semiconductor chip in which the above units are arranged in parallel.

The removed region 111 is a region formed by: forming, on the silicon substrate 101, the SiO₂ layer 102, the silicon layer 103, the buffer layer 104, the GaN layer 105, and the AlGaN layer 106 in this order, and then removing, by etching, part of a perimeter of the silicon layer 103, the buffer layer 104, the GaN layer 105, and the AlGaN layer 106. Here, the SiO₂ layer 102 may function as an etching stop layer.

Likewise, in the nitride semiconductor device 12, the configuration of the removed region 111 allows suppressing, between the silicon substrate 101 and each of the source electrode 107, the drain electrode 108, and the gate electrode 109, the leakage current passing via the edge sidewalls of the silicon layer 103, the buffer layer 104, the GaN layer 105, and the AlGaN layer 106. Thus, it is possible to realize a configuration which increases resistivity of the region that easily passes the leakage current, and thereby to suppress the substrate current flowing from the electrodes into the substrate even when the potential of the electrodes is increased, thus increasing breakdown voltage and preventing breakdown of the nitride semiconductor device.

Note that the same advantageous effect can be produced as with the nitride semiconductor device 12 even in the case of forming the increased-resistivity region 110 by ion implantation at the same position, instead of the removed region 111 provided in part of the perimeter of the nitride semiconductor device 12.

That is, the removed region 111 and the increased-resistivity region 110 need not be formed in part of a perimeter of each of the units which includes the gate electrode, the source electrode, and the drain electrode, but should preferably be formed in part of the perimeter of each semiconductor chip that functions as a device.

Note that specific resistance of the silicon layer 103 should preferably be 1 k Ωcm or higher. With the specific resistance lower than 1 k Ω·cm, transient current passes through the silicon layer 103 when the transistor function is turned on and off, thus resulting in a problem of heat generation within the device.

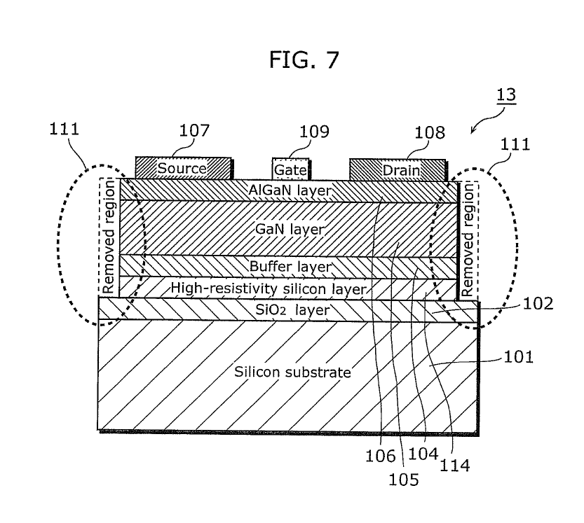

FIG. 7 is a cross-sectional view of the configuration of a nitride semiconductor device according to a third variation of the first embodiment of the present invention. A nitride semiconductor device 13 in the figure includes: the silicon substrate 101, the SiO₂ layer 102, a high-resistivity silicon layer 114, the buffer layer 104, the GaN layer 105, the AlGaN layer 106, the source electrode 107, the drain electrode 108, and the gate electrode 109. The nitride semiconductor device 13 shown in FIG. 7 is different from the nitride semiconductor device 11 shown in FIG. 2 in that the nitride semiconductor device 13 includes a high-resistivity silicon layer. The following will omit the description of the same points as those described in the nitride semiconductor device 11 in FIG. 2, and will describe only the difference.

The high-resistivity silicon layer 114 is a silicon layer having an increased resistivity of 1 k Ωcm or higher. By thus increasing resistivity of the silicon layer, it is possible to significantly increase breakdown voltage even when the film thickness of the SiO₂ layer 102 is the same.

The reason for this is described below. First, it is assumed that a nitride transistor is formed on a normal silicon substrate to which the SOI substrate is not applied. In this case, when grounding the potential of a back of the substrate (substrate grounding), high drain voltage is applied between the drain electrode and the substrate. On the other hand, floating the substrate potential turns the potential in the back into an intermediate potential between the drain voltage and the source potential, which reduces the voltage to be applied between the drain electrode and the substrate located immediately under the drain electrode, thus allowing increasing breakdown voltage as compared to the case of substrate grounding. Here, by applying the SOI substrate, it is possible to achieve, even in the case of substrate grounding, breakdown voltage equivalent to the breakdown voltage in the floating state of the substrate potential of the device on a normal silicon substrate. Here, by increasing the resistivity of the silicon layer, all the SiO₂ layer 102, the high-resistivity silicon layer 114, the buffer layer 104, the GaN layer 105, and the AlGaN layer 106 function as insulators, thus allowing further increasing breakdown voltage.

Note that the same advantageous effect can be produced as with the nitride semiconductor device 12 even in the case of forming the increased-resistivity region 110 by ion implantation at the same position, instead of the removed region 111 provided in part of the perimeter of the nitride semiconductor device 12.

Note that in the nitride semiconductor devices 10, 11, 12, and 13 according to the present embodiment, one of the silicon layer 103 and the high-resistivity silicon layer 114 that are on the SiO₂ layer may be sapphire having high insulating property. In addition, the configuration including sapphire need not include the SiO₂ layer 102. With this, since the sapphire layer on the silicon substrate 101 is an insulator having an extremely high resistivity, a longitudinal voltage of the device is divided among all the layers including the sapphire layer in addition to the GaN layer 105 and the buffer layer 104, thus allowing increasing breakdown voltage.

Note that in the nitride semiconductor devices 10, 11, 12, and 13 according to the present embodiment, the silicon layer 103 or the high-resistivity silicon layer 114 on the SiO₂ layer may be sapphire having high insulating property. In this case, due to a small difference between the lattice constants of the SiC and the buffer layer 104, in addition to high resistivity of the SiC, it is possible to reduce defect density of the nitride layer, thus allowing further increasing breakdown voltage.

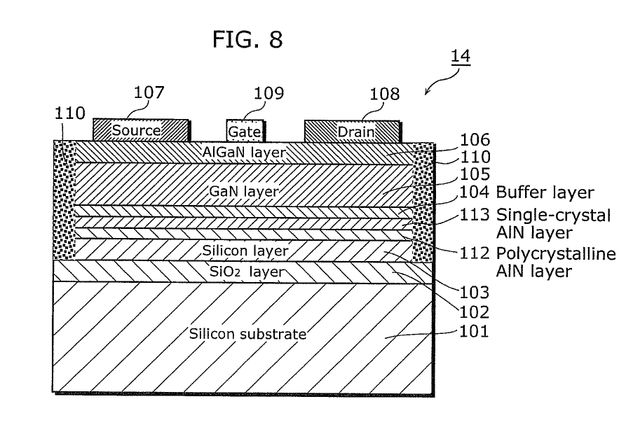

FIG. 8 is a cross-sectional view of the configuration of a nitride semiconductor device according to a fourth variation of the first embodiment of the present invention. A nitride semiconductor device 14 in the figure includes: the silicon substrate 101, the SiO₂ layer 102, the silicon layer 103, the buffer layer 104, the GaN layer 105, the AlGaN layer 106, the source electrode 107, the drain electrode 108, the gate electrode 109, the increased-resistivity region 110, a polycrystalline AlN layer 112, and a single-crystal AlN layer 113. The nitride semiconductor device 14 shown in FIG. 8 is different from the nitride semiconductor device 10 shown in FIG. 1 in that the polycrystalline AlN layer 112 and the single-crystal AlN layer 113 are formed between the silicon layer 103 and the buffer layer 104. The following will omit the description of the same points as those described in the nitride semiconductor device 10 in FIG. 1, and will describe only the difference.

The single-crystal AlN layer 113 is formed, for example, as part of a second buffer layer so as to secure crystallinity of the buffer layer 104 and the GaN layer 105 having a periodic structure in which a heterostructure including an Al_{X}Ga_{1-X}N layer (0≦X<1) and an Al_{Y}Ga_{1-Y}N layer (0<Y≦1) is repeated.

The polycrystalline AlN layer 112 is part of the second buffer layer formed between the silicon layer 103 and the single-crystal AlN layer 113. In the case of not forming the polycrystalline AlN layer 112, polarization charge is accumulated at the interface of the single-crystal AlN layer 113 and the silicon layer 103, and forms a channel in a face direction. The presence of the polycrystalline AlN layer 112 allows removing an electron-accumulating layer derived from the polarization charge that should be accumulated at the interface of the single-crystal AlN layer 113 and the silicon layer 103, thus further increasing breakdown voltage.

Note that the same advantageous effect can be produced as in the nitride semiconductor device 14 even in the case of forming, by etching, the removed region 111 at the same position, instead of the increased-resistivity region 110 provided in the perimeter of the nitride semiconductor device 14.

As described above, according to the nitride semiconductor device according to the first embodiment of the present invention, a portion between the electrodes and the silicon substrate is insulated by the insulating film, and a current leakage path due to crystal fault is suppressed, and furthermore the leakage current via the device edge is suppressed, so that it is possible to suppress substrate current flowing from the electrodes into the substrate even when the potential of the electrodes increases, thus allowing preventing breakdown of the nitride semiconductor device.

Note that the present embodiment has described an example of the field-effect transistor that is a three-terminal device, but the same advantageous effect can be produced even in the case of a Schottky barrier diode that is a two-terminal device.

### Embodiment 2

A nitride semiconductor device according to the present embodiment includes a p-type silicon substrate on which: an n-type silicon layer, a buffer layer, a first nitride semiconductor layer, a second nitride semiconductor layer having a greater bandgap than the first nitride semiconductor layer, and an electrode are stacked in this order. Furthermore, edge sidewalls of the n-type silicon layer, the buffer layer, and the first and second nitride semiconductor layers contact a region having increased resistivity. With this, when the electrodes are positively biased with respect to the p-type silicon substrate, a depletion layer is formed as a result of reverse biasing of the p-n conjunction, and a current leakage path due to crystal fault is suppressed, and furthermore leakage current via a device edge is suppressed, thus allowing realizing higher breakdown voltage.

The following will describe a second embodiment of the present invention with reference to the drawings.

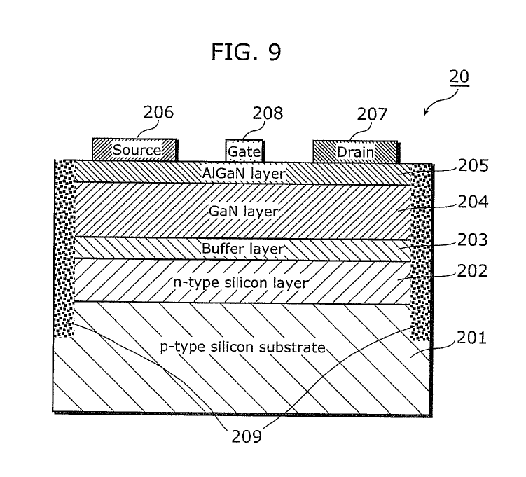

FIG. 9 is a cross-sectional view of a configuration of a nitride semiconductor device according to the second embodiment of the present invention. A nitride semiconductor device 20 in the figure includes: a p-type silicon substrate 201, an n-type silicon layer 202, a buffer layer 203, a GaN layer 204, an AlGaN layer 205, a source electrode 206, a drain electrode 207, a gate electrode 208, and an increased-resistivity region 209.

The nitride semiconductor device 20 shown in FIG. 9 is different from the nitride semiconductor device 10 shown in FIG. 1 in configuration in that the silicon substrate is of p-type, and includes the n-type silicon layer 202 which is stacked instead of the SiO₂ layer 102 and the silicon layer 103. The following will omit the description of the same points as those in the first embodiment, and will describe only the difference.

The p-type silicon substrate 201 is a silicon substrate of p-type, and forms a p-n junction with an n-type silicon layer 202 that is an upper layer.

The n-type silicon layer 202 is a silicon layer of n-type and is stacked on the p-type silicon substrate 201, forming a p-n junction with the p-type silicon substrate 201 that is a lower layer. In addition, the p-n junction thus formed forms a depletion layer when reversely biased, thus having a function to suppress a current passing through the p-n junction even against a high electric field.

Note that the breakdown voltage between the silicon substrate 201 and the drain electrode 207 should preferably be 100 V or higher in order to secure the breakdown voltage against the high electric field as described above.

The buffer layer 203 is stacked on the n-type silicon layer 202, and has a function to reduce the difference between thermal expansion coefficients of an n-type silicon layer 202 that is a lower layer and the GaN layer 204 and the AlGaN layer 205 that are upper nitride semiconductor layers.

The GaN layer 204 and the AlGaN layer 205 have the same configuration and function as the GaN layer 105 and the AlGaN layer 106 in the first embodiment, respectively.

The source electrode 206, the drain electrode 207, and the gate electrode 208 have the same configuration and function as the source electrode 107, the drain electrode 108, and the gate electrode 109 in the first embodiment.

The increased-resistivity region 209 is formed in edge sidewalls of a layered body from the p-type silicon substrate 201 to the AlGaN layer 205. The method of forming the increased-resistivity region 209 is represented by ion implantation, but another technique may also used. For example, as in the nitride semiconductor devices 11 to 13 according to the first embodiment, the same effect can be produced even in the case of forming, by etching, the removed region 111 at the same position, instead of the increased-resistivity region 209.

The increased-resistivity region 209 has a function to effectively reduce leakage current that flows from the drain electrode 207 to the p-type silicon substrate 201 via the edge sidewalls of the layered body. With this, it is possible to realize a transistor having an extremely high breakdown voltage.

With the configuration described above, the nitride semiconductor device 20 functions as a high-power field-effect transistor.

The following will describe an operation of the above-described nitride semiconductor device 20 as a field-effect transistor when the transistor is in an off-state. In this off-state, by setting the voltage between the gate electrode 208 and the source electrode 206 to a threshold voltage of the transistor or lower, for example, to −5V, a positive voltage of 200 V, for example, is applied to the drain electrode 207. In this state, nearly 200 V is applied between the drain electrode 207 and the source electrode 206; however, by providing a large distance of, for example, approximately 5 μm between the drain electrode 207 and the gate electrode 208, a sufficient breakdown voltage can be secured between the gate and drain electrodes, thus causing no breakdown.

On the other hand, this results in applying a large electric field between the drain electrode 207 and the p-type silicon substrate 201. In the conventional transistor, device breakdown occurs between the drain electrode and the silicon substrate. In contrast, in the nitride semiconductor device 20 according to an implementation of the present invention, the electric field is supported by a depletion layer that is formed when the p-n junction between the p-type silicon substrate 201 and the silicon layer 202 is reversely biased.

Note that any plane orientation of the p-type silicon substrate 201 may be adopted, such as (100) and (111).

In addition, the film thickness of the n-type silicon layer 202 should preferably be 5 μm or less. With this, a sufficient breakdown voltage is secured for the transistor.

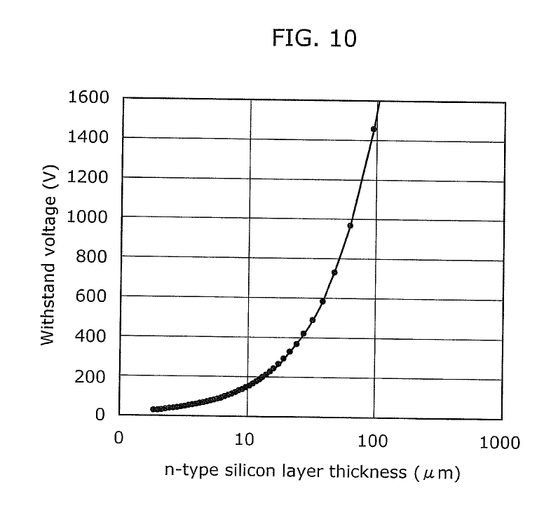

FIG. 10 is a graph showing dependence of breakdown voltage on an n-type silicon-layer film thickness in the nitride semiconductor device according to the second embodiment of the present invention. The graph shown in the figure indicates that the breakdown voltage is dramatically increased when the film thickness of the n-type silicon layer 202 is 5 μm or more. By selecting this film thickness range, no breakdown occurs between the drain electrode 207 and the p-type silicon substrate 201, thus realizing a high breakdown voltage transistor.

In addition, it is preferable that the n-type silicon layer 202 have a carrier concentration of 5×10¹⁵ cm⁻³ or less. With this, the nitride semiconductor device 20 can secure sufficient breakdown voltage.

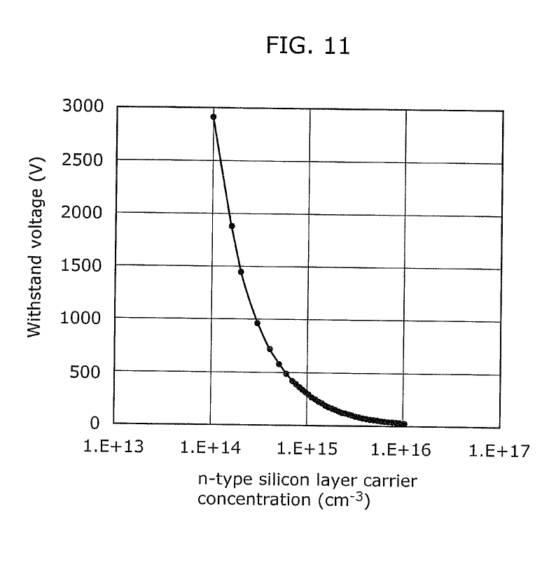

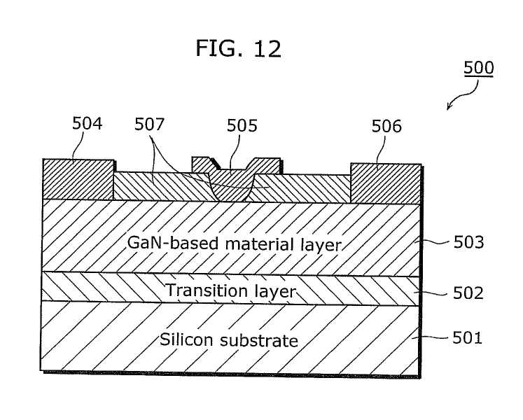

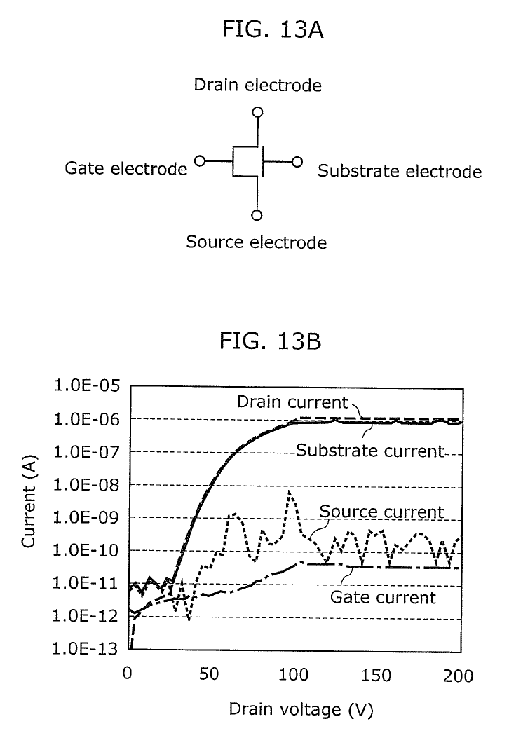

FIG. 11 is a graph showing a relationship between carrier concentration and breakdown voltage of the n-type silicon layer included in the nitride semiconductor device according to the second embodiment of the present invention. The graph shown in the figure indicates that the breakdown voltage of the nitride semiconductor device 20 is dramatically increased when the n-type silicon layer 202 has a carrier concentration of 5×10¹⁵ cm⁻³ or less.

In addition, for example, it is preferable that the buffer layer 203 have a periodic structure in which a heterostructure including an Al_{X}Ga_{1-X}N layer (0≦X<1) and an Al_{Y}Ga_{1-Y}N layer (0<Y≦1) is repeated, and particularly have a structure in which a heterostructure of AlN and GaN is periodically stacked into multiple layers. Since this configuration includes multiple heterobarriers against electrons, carrier conduction between the drain electrode and the silicon substrate is suppressed, thus allowing further increasing breakdown voltage between the drain electrode and the silicon substrate.

Note that the nitride semiconductor device 20 described in FIG. 9 illustrates only a semiconductor chip which includes a unit made up of the gate electrode 208, the source electrode 206, and the drain electrode 207; however, even in the case of including, as a constituent element, a semiconductor chip in which a plurality of such units are arranged, the same advantageous effect can be produced as with the nitride semiconductor device described in FIG. 9. For example, this corresponds to a nitride semiconductor device in which the removed region or the increased-resistivity region is provided in part of a perimeter of a multiple-finger transistor chip as described in FIG. 6A.

As described above, according to the nitride semiconductor device according to the second embodiment of the present invention, when the electrodes are positively-biased with respect to the p-type silicon substrate, a depletion layer is formed as a result of reverse biasing of the p-n conjunction, and current leakage due to crystal fault is suppressed, and furthermore leakage current via a device edge is suppressed, thus allowing realizing higher breakdown voltage.

Note that the present embodiment has described an example of a field-effect transistor that is a three-terminal device, but the same advantageous effect can be produced even in the case of a Schottky barrier diode that is a two-terminal device.

Thus far, the nitride semiconductor device according to the first and second embodiments of the present invention has been described, but the nitride semiconductor device according to an implementation of the present invention is not limited to these embodiments. Those skilled in the art will readily appreciate that many modifications are possible in the exemplary embodiments without departing from the novel teachings and advantages of this invention. Accordingly, all such modifications are intended to be included within the scope of this invention.

### INDUSTRIAL APPLICABILITY

The present invention is applicable as a GaN-based power device on a silicon substrate, which requires high breakdown voltage characteristics, and particularly is best suited for use in a power amplifier including the power device. With this, it is possible to sufficiently extract a potential of the nitride semiconductor device expected as a semiconductor material for a power device, and thus the industrial value thereof is extremely high.

### REFERENCE SIGNS LIST

10, 11, 12, 13, 14 Nitride semiconductor device
101 Silicon substrate
102 SiO₂ layer
103 Silicon layer
104, 203 Buffer layer
105, 204 GaN layer
106, 205 AlGaN layer
107, 206, 504 Source electrode
108, 207, 506 Drain electrode
109, 208, 505 Gate electrode
110, 209 Increased-resistivity region
111 Removed region
112 Polycrystalline AlN layer
113 Single-crystal AlN layer
114 High-resistivity silicon layer
201 P-type silicon substrate
202 N-type silicon layer
500 GaN-based transistor
501 Silicon substrate
502 Transition layer
503 GaN-based material layer
507 Passivation film

1. A nitride semiconductor device, comprising:
a silicon substrate;
a current suppression layer which is stacked on said silicon substrate and suppresses current flowing into said silicon substrate;
a buffer layer stacked on said current suppression layer;
a first nitride semiconductor layer stacked on said buffer layer;
a second nitride semiconductor layer stacked on said first nitride semiconductor layer and having a bandgap greater than a bandgap of said first nitride semiconductor layer; and
an electrode formed on said second nitride semiconductor layer,
wherein an edge sidewall of each of said buffer layer, and said first and second nitride semiconductor layers contacts an increased-resistivity region.

2. The nitride semiconductor device according to claim 1,
wherein said increased-resistivity region is a region formed by implanting ions into part of a perimeter of said buffer layer and said first and second nitride semiconductor layers.

3. The nitride semiconductor device according to claim 1,
wherein said increased-resistivity region is a region formed by removing, by etching, part of a perimeter of said buffer layer and said first and second nitride semiconductor layers.

4. The nitride semiconductor device according to claim 1, further comprising
a silicon layer formed between said current suppression layer and said buffer layer, and having an edge sidewall in contact with said increased-resistivity region,
wherein said current suppression layer is a SiO₂ layer having a film thickness of 100 nm or more.

5. The nitride semiconductor device according to claim 4,
wherein the film thickness of said SiO₂ layer is 3 μm or less.

6. The nitride semiconductor device according to claim 4,
wherein resistivity of said silicon layer is 1 k Ωcm or more.

7. The nitride semiconductor device according to claim 4,
wherein a surface orientation of said silicon layer is tilted at 5 degrees or less with respect to a surface.

8. The nitride semiconductor device according to claim 4,
wherein the film thickness of said silicon layer is 5 μm or less.

9. The nitride semiconductor device according to claim 4,
wherein said buffer layer includes a polycrystalline AlN layer, and a single-crystal AlN layer formed on said polycrystalline AlN layer.

10. The nitride semiconductor device according to claim 1, further comprising
a high-resistivity layer formed between said current suppression layer and said buffer layer,
wherein said high-resistivity layer is a sapphire layer having a film thickness of 100 nm or more.

11. The nitride semiconductor device according to claim 1, further comprising
a high-resistivity layer formed between said current suppression layer and said buffer layer,
wherein said high-resistivity layer is a SiC layer having a film thickness of 100 nm or more.

12. The nitride semiconductor device according to claim 1,
wherein said current suppression layer is an n-type silicon layer having an edge sidewall in contact with said increased-resistivity region, and
said silicon substrate is a p-type silicon substrate.

13. The nitride semiconductor device according to claim 12,
wherein the film thickness of said n-type silicon layer is 5 μm or more.

14. The nitride semiconductor device according to claim 12,
wherein said n-type silicon layer has a carrier concentration of 5×10¹⁵ cm⁻³ or less.

15. The nitride semiconductor device according to claim 1,
wherein said buffer layer includes a periodic structure in which a heterostructure including an Al_{X}Ga_{1-X}N layer (0≦X<1) and an Al_{Y}Ga_{1-Y}N layer (0<Y≦1) is repeated.
